(19) United States
(12) Patent Application Publication
(10) Pub. No.: US 2008/0096381 A1
(43) Pub. Date: Apr. 24, 2008

(54) Atomic layer deposition process for iridium barrier layers

(76) Inventors: Joseph H. Han, San Jose, CA (US); Harsono S. Simka, Paseo Lado, CA (US); Adrien R. Adrien, Beaverton, OR (US); Juan E. Dominguez, Hillsboro, OR (US); John J. Plombon, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/581,143

(22) Filed: Oct. 12, 2006

(51) Int. Cl. H01L 21/4763; C23C 16/00

(52) U.S. Cl. 438/643; 118/715; 438/618; 438/637

(57) ABSTRACT

An iridium barrier and adhesion layer for use with copper interconnects within integrated circuits is formed using an atomic layer deposition (ALD) process. The ALD process uses an organometallic iridium precursor and at least one co-reactant.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. This gives rise to issues such as trench overhang during the copper seed deposition process, leading to pinched-off trench openings and inadequate electroplating gapfill. Additionally, as trenches decrease in size, the ratio of barrier metal to copper metal in the overall interconnect structure increases, thereby increasing the electrical line resistance and RC delay of the interconnect.

One approach to addressing these issues is to reduce the thickness of the TaN/Ta or TaN/Ru stack, which widens the available gap for subsequent metallization and increases the final copper volume fraction. Unfortunately, this is often limited by the non-conformal characteristic of PVD deposition techniques. Accordingly, alternative techniques for reducing the thickness of the barrier and adhesion layer are needed.

### BRIEF DESCRIPTION OF THE DRAWINGS

FIGS. 1A to 1E illustrate a conventional damascene process for forming metal interconnects.

FIG. 2 illustrates an iridium barrier and adhesion layer.

FIG. 3 is a method of forming an iridium layer using an atomic layer deposition process in accordance with an implementation of the invention.

### DETAILED DESCRIPTION

Described herein are systems and methods of fabricating an iridium layer that functions as a barrier layer and an adhesion layer for a copper interconnect in an integrated circuit application. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention; however, the order of description should not be construed to imply that these operations are necessarily order dependent. In particular, these operations need not be performed in the order of presentation.

Implementations of the invention provide an iridium layer deposited by way of an atomic layer deposition (ALD) process that may be used to replace the conventional barrier layer and adhesion layer used for copper interconnects in integrated circuit applications. For instance, an ALD iridium layer prepared in accordance with the invention may be used to replace the conventional Ta/TaN or Ru/TaN stack with a single layer. The result is a thinner barrier and adhesion layer that substantially reduces the occurrence of trench overhang and void formation in the copper interconnect. The thinner barrier and adhesion layer also increases the final copper volume fraction of the interconnect, thereby improving electrical line resistance.

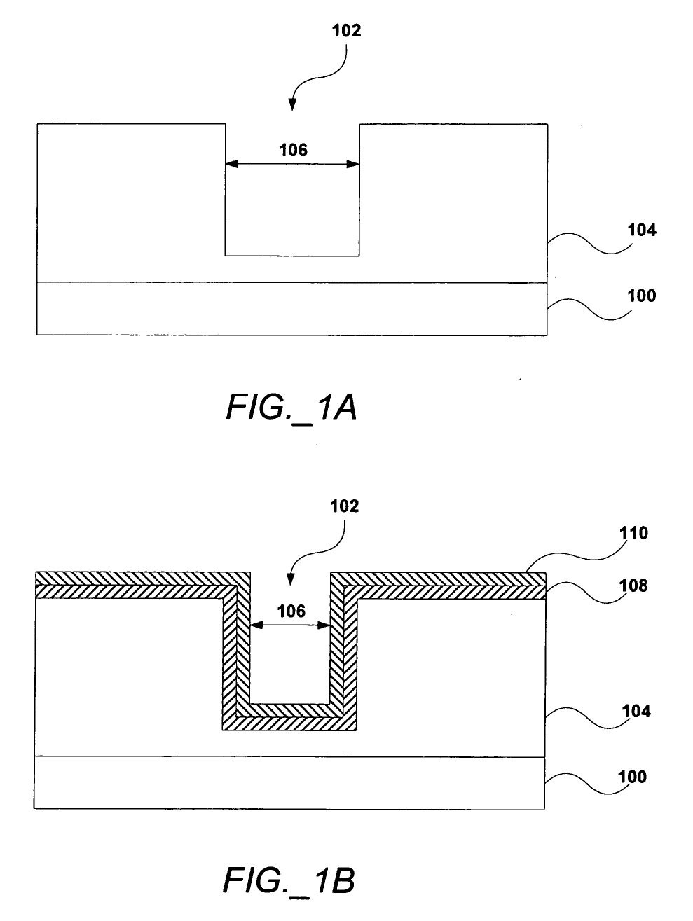

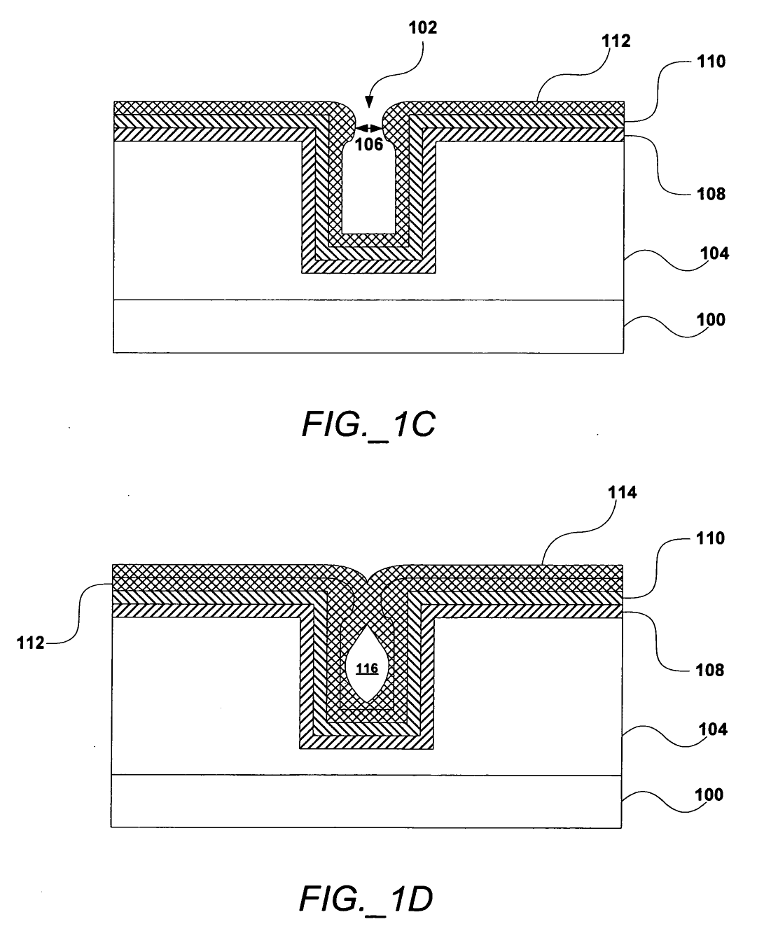

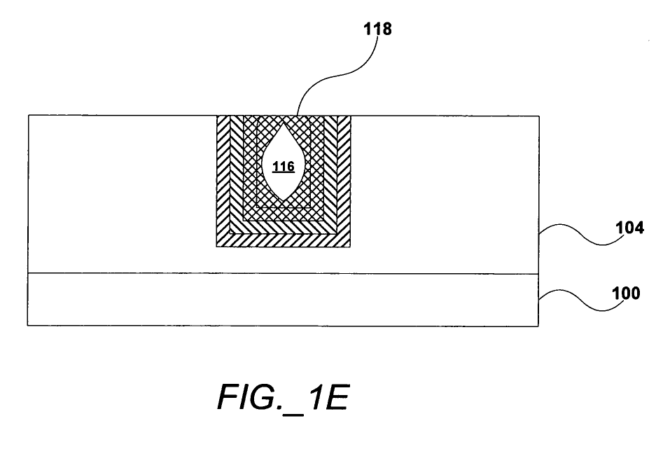

For reference, FIGS. 1A to 1E illustrate a conventional damascene process for fabricating copper interconnects on a semiconductor wafer. FIG. 1A illustrates a substrate 100, such as a semiconductor wafer, that includes a trench 102 that has been etched into a dielectric layer 104. The trench 102 includes a gap 106 through which metal may enter during metallization processes.

FIG. 1B illustrates the trench 102 after a conventional barrier layer 108 and a conventional adhesion layer 110 have been deposited. The barrier layer 108 prevents copper metal from diffusing into the dielectric layer 104. The adhesion layer 110 enables copper metal to become deposited onto the barrier layer 108. The barrier layer 108 is generally formed using a material such as tantalum nitride TaN) and is deposited using a PVD process. The barrier layer 108 may be around 3 Angstroms (├) to 10 nanometers (nm) thick, although it is generally around 5 nm thick. The adhesion layer 110 is generally formed using a metal such as tantalum (Ta) or ruthenium (Ru) and is also deposited using a PVD process. The adhesion layer 110 is generally around 5 nm to 10 nm thick.

After the adhesion layer 110 is formed, the conventional damascene process of FIG. 1 uses two independent deposition processes to fill the trench 102 with copper metal. The first deposition process is a PVD process that forms a non-conformal copper seed layer. The second deposition process is a plating process, such as an electroplating (EP) process or an electroless plating (EL) process, that deposits a bulk copper layer to fill the trench 102.

FIG. 1C illustrates the trench 102 after a conventional copper seed layer 112 has been deposited onto the adhesion layer 110 using a PVD process. The copper seed layer 112 enables or catalyzes a subsequent plating process to fill the interconnect with copper metal. FIG. 1D illustrates the trench 102 after an EP or EL copper deposition process has been carried out. Copper metal 114 enters the trench through the gap 106 where, due to the narrow width of the gap 106, issues such as trench overhang and pinching off of the trench opening may occur that lead to defects in the plating step. For instance, as shown in FIG. 1D, trench overhang may occur that pinches off the opening of the trench 102, creating a void 116 that will appear in the final interconnect structure.

FIG. 1E illustrates the trench 102 after a chemical mechanical polishing (CMP) process is used to planarize the deposited copper metal 114. The CMP results in the formation of a metal interconnect 118. As shown, the metal interconnect 118 includes the void 116 that was formed when the available gap 106 was too narrow and the resulting trench overhang pinched off the trench opening. Furthermore, a substantial portion of the metal interconnect 118 comprises Ta and/or Ru from the adhesion layer 110 and the barrier layer 108, which decreases the percentage of copper in the final interconnect and increases the line resistance and RC delay.

Other potential fabrication methods for copper interconnects suffer from drawbacks as well. For instance, the use of an iridium barrier layer deposited using a physical vapor deposition (PVD) process may still result in significant trench overhang and poor sidewall coverage. This also often leads to voids in the copper interconnect.

In accordance with the invention, rather than employing a Ta/TaN stack or a PVD iridium layer, a novel ALD process is used to form an ALD iridium layer. Atomic layer deposition is an activated deposition process (e.g., using thermal, plasma, or other activation methods) where reactants are introduced separately to ensure that film growth is limited by surface reactions rather than species transport. As such, conformal films are grown with much more precise thickness control in contrast to other processes such as PVD or chemical vapor deposition (CVD). One example of reactants that may be used in an ALD process to form an iridium layer include Ir(acac)₃ (where Ir=iridium and acac=acetylacetonato) combined with oxygen (O₂). And because of the similarity in chemistry between of rhodium (Rh) and iridium, iridium analogues of many rhodium precursors may be used as precursors as well. The resultant ALD iridium layer does not suffer from the issues that plague conventional barrier and adhesion layers.

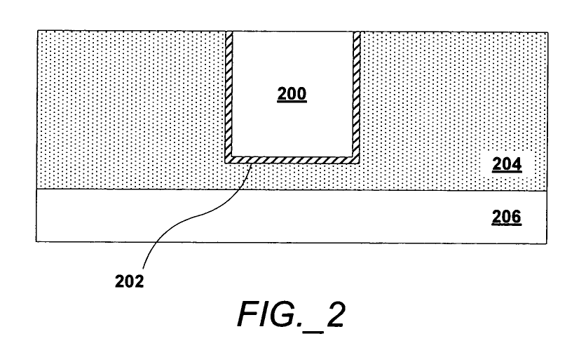

FIG. 2 illustrates a copper interconnect 200 formed within a trench of a dielectric layer 204 upon a substrate 206. The copper interconnect 200 is used within an integrated circuit (IC) die, generally within metallization layers used to interconnect transistors and other structures formed on a device layer of the IC die. The substrate 206 may be a portion of a semiconductor wafer. In accordance with an implementation of the invention, an iridium layer 202 is formed between the copper interconnect 200 and the dielectric layer 204 and functions as a barrier layer to prevent the copper metal from diffusing into the dielectric layer 204. The iridium layer 202 also functions as an adhesion layer that enables copper to be deposited within the trench to form the copper interconnect 200, thereby eliminating the need for a separate copper seed layer. In implementations of the invention, the iridium layer may have a thickness that ranges from 1 nm to 10 nm, though typically the iridium layer will have a thickness of around 3 nm to 5 nm.

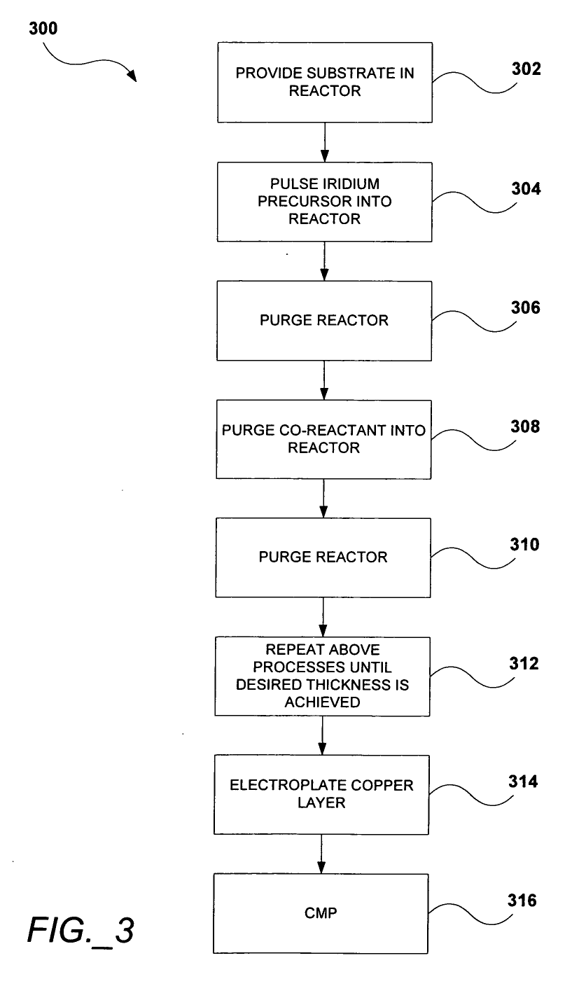

FIG. 3 is a method 300 of forming a copper interconnect having an ALD iridium layer in accordance with an implementation of the invention. The method 300 begins by providing a semiconductor substrate onto which a metal interconnect, such as a copper interconnect, may be formed (302). For instance, the semiconductor substrate may be a silicon wafer that includes a dielectric layer deposited on its surface. The dielectric layer may include at least one trench in which the copper interconnect is to be formed. The dielectric layer may be formed from conventional materials used for dielectric layers, including but not limited to silicon dioxide (SiO₂) and carbon doped oxide (CDO). The substrate may be housed in a reactor in preparation for the ALD process. The substrate may be heated within the reactor to a temperature between around 100° C. and around 400° C. while the reactor pressure may range between around 0.1 Torr and 3.0 Torr.

In accordance with an implementation of the invention, at least one pulse of an iridium precursor is introduced into the reactor (304). Organometallic precursors that may be used for the iridium precursor pulse include carbonyls, phosphine analogues, hydrocarbon ligands, and mixed ligands. Organometallic precursors that are carbonyls include, but are not limited to, Ir₄(CO)₁₂, Ir(CO)_{y}Br_{4-y}, Ir(CO)_{y}Cl_{4-y}, Ir(CO)_{y}I_{4-y}, HIr(CO)₄, and (Ir(CO)₂Cl)₂; organometallic precursors that are phosphine analogues include, but are not limited to, IrH₃(PPh₃)₂ (where Ph=phenyl), IrH₂Cl(PPh₃)₃, and (IrCl(PF₃)₂)₂; organometallic precursors that are hydrocarbon ligands include, but are not limited to, Ir(acac)₃, Ir(allyl)₂(acac), Ir(hfac)(C₂H₄)₂ (where hfac=hexafluoroacetylacetonate), Ir(Cp)₂(where Cp=cyclopentadienyl), Ir(Cp)(CpMe₅) (where Me=methyl), and Ir(Benzene)(CpMe₅); and organometallic precursors that are mixed ligands include, but are not limited to, IrCl(CO)(PPh₃)₂, IrH(CO)(PPh₃)₃, IrH₂Cl(CO)(PPh₃)₂, IrCl₂(Cp)(PPh₃), Ir(CO)(Cp)(PPh₃), MeCpIr(COD) (where COD=cyclooctadiene), and MeCplr(norboradiene). In some implementations of the invention, the above listed precursors may be modified by mixing of the ratio of ligands or substituting analogues of ligands. In other implementations, more than one of the iridium precursors, each having different ligands, may be used simultaneously in the ALD process.

In various implementations of the invention, the following process parameters may be used for the iridium precursor pulse. The iridium precursor pulse may have a duration that ranges from around 1 second to around 10 seconds with a flow rate of up to 10 standard liters per minute (SLM). The specific number of iridium precursor pulses may range from 1 pulse to 200 pulses or more depending on the desired thickness of the final iridium layer. The iridium precursor temperature may be between around 80° C. and 250° C. while the vaporizer temperature may be around 60° C. to around 250° C.

A heated carrier gas may be employed with a temperature that generally ranges from around 60° C. to around 200° C. Carrier gases that may be used here include, but are not limited to, argon (Ar), xenon (Xe), helium (He), or nitrogen (N₂). The flow rate of the carrier gas may range from around 100 standard cubic centimeters (SCCM) to around 200 SCCM.

The delivery line temperature is kept hot enough to prevent the precursor from condensing without causing the precursor to decompose. This generally means the delivery line temperature will range from around 60° C. to around 250° C., and will generally be around 120° C. Before discharge, the delivery line pressure may be set to around 0 to 5 psi, the orifice may be between 0.1 mm and 1.0 mm in diameter, and the charge pulse may be between 1 second and 5 seconds. The equilibration time with the valves closed may be 1 second to 5 seconds and the discharge pulse may be 1 second to 5 seconds.

Finally, an RF energy source may be applied at a power that ranges from 5 Watts (W) to 200 W and at a frequency of 13.56 MHz, 27 MHz, or 60 MHz. It should be noted that the scope of the invention includes any possible set of process parameters that may be used to carry out the implementations of the invention described herein.

After the at least one pulse of the organometallic precursor, the reactor may be purged (306). The purge gas may be an inert gas such as Ar, Xe, N₂, He, or forming gas and the duration of the purge may range from 0.1 seconds to 60 seconds, depending on the ALD reactor configurations and other deposition conditions. In most implementations of the invention, the purge may range from 2 seconds to 10 seconds.

In accordance with an implementation of the invention, at least one pulse of a co-reactant is then introduced into the reactor to react with the organometallic precursor (308). In some implementations the co-reactant may be atomic hydrogen, molecular hydrogen, oxygen (O₂), BH₃, B₂H₆, catechol-borane, NH₃, methane (CH₄), silane (SiH₄), GeH₄, metal hydrides, carbon monoxide (CO), and/or ethanol. In other implementations, a plasma source may be used as a co-reactant to adjust growth rates and to control film morphology and impurity concentration. For instance, a hydrogen (H₂) plasma may be employed as a co-reactant in addition to or in lieu of the co-reactants provided above. In further implementations, a metal precursor may be used as a co-reactant to alloy with the iridium metal. Such metal precursors may include precursors for aluminum, copper, ruthenium, and tantalum. In various implementations of the invention, any combination of the co-reactants listed above, including the plasma and metal precursors, may be used.

Conventional process parameters may be used for the co-reactant pulse. For instance, in implementations of the invention, the process parameters for the co-reactant pulse include, but are not limited to, a co-reactant pulse duration of between around 1 second and 10 seconds, a co-reactant flow rate of up to 10 SLM, a reactor pressure between around 0.1 Torr and 3.0 Torr, a co-reactant temperature between around 80° C. and 200° C., a substrate temperature between around 100° C. and around 250° C., and an RF energy source that may be applied at a power that ranges from 5 W to 200 W and at a frequency of 13.56 MHz, 27 MHz, or 60 MHz. It should be noted that the scope of the invention includes any possible set of process parameters that may be used to carry out the implementations of the invention described herein.

For the H₂ plasma, process parameters that may be used include a flow rate of around 200 SCCM to around 600 SCCM, though the H₂ plasma flow rate will generally be around 300 SCCM. The H₂ plasma may be pulsed into the reactor with a pulse duration of around 2 seconds to around 10 seconds, with a pulse duration of around 3 seconds often being used. The plasma power may range from around 5 W to around 200 W and will generally range from around 60 W to around 200 W.

After the at least one pulse of the co-reactant, the reactor may again be purged (310). The purge gas may be an inert gas such as Ar, Xe, N₂, He, or forming gas and the duration of the purge may range from 0.1 seconds to 60 seconds, depending on the ALD reactor configurations and other deposition conditions. In most implementations of the invention, the purge may range from 2 seconds to 20 seconds.

The above processes result in the formation of an iridium layer on the dielectric layer. If the iridium layer has not yet reached a desired thickness, the above processes may be repeated as necessary until the desired thickness is reached (312).

Following the formation of the iridium layer, the substrate may be transferred to a plating bath and a plating process may be carried out to deposit a copper layer over the iridium layer (314). The copper layer fills the trench with copper to form the copper interconnect. The copper metal enters the trench where, due to the relatively large width of the trench enabled by the thin iridium layer, issues such as trench overhang are reduced or eliminated. In some implementations, the plating bath is an electroplating bath and the plating process is an electroplating process. In other implementations, the plating bath is an electroless plating bath and the plating process is an electroless plating process. In further implementations, a copper seed layer may be deposited using an electroless plating process before the copper layer is deposited. Finally, a chemical mechanical polishing (CMP) process may be used to planarize the deposited copper metal and finalize the copper interconnect structure (316).

It should be noted that in alternate implementations of the invention, the order of reactants may be changed. For instance, the iridium layer fabrication process may begin by pulsing one or more of the co-reactants into the reactor. The co-reactant pulse may be followed by a reactor purge. Next, the fabrication process may pulse the iridium precursor into the reactor where the precursor reacts with the co-reactant to form the iridium layer.

Accordingly, a process has been described that enables the growth of conformal thin films of iridium that may be used in sub-100 nm VLSI interconnect structures. The resulting iridium layer has properties to resist copper diffusion, resist oxidation, improve adhesion, and allow direct copper plating without the need for an additional copper seed layer. Furthermore, the ALD process described herein takes place at temperatures that are compatible with back-end semiconductor process technologies (i.e., less than 400° C.). And finally, the thinness of the iridium barrier/adhesion layer allows for a higher overall copper line volume leading to lower line resistance and RC delay.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a semiconductor substrate in a reactor, wherein the semiconductor substrate includes a trench etched into a dielectric layer;
pulsing an iridium precursor into the reactor proximate to the semiconductor substrate, wherein the iridium precursor comprises at least one of Ir₄(CO)₁₂, Ir(CO)_{y}Br_{4-y}, Ir(CO)_{y}Cl_{4-y}, Ir(CO)_{y}I_{4-y}, HIr(CO)₄, (Ir(CO)₂Cl)₂, IrH₃(PPh₃)₂, IrH₂Cl(PPh₃)₃, (IrCl(PF₃)₂)₂, Ir(acac)₃, Ir(allyl)₂(acac), Ir(hfac)(C₂H₄)₂, Ir(Cp)₂, Ir(Cp)(CpMe₅), Ir(Benzene)(CpMe₅), IrCl(CO)(PPh₃)₂, IrH(CO)(PPh₃)₃, IrH₂Cl(CO)(PPh₃)₂, IrCl₂(Cp)(PPh₃), Ir(CO)(Cp)(PPh₃), MeCplr(COD), or MeCplr(norboradiene);
purging the reactor with a purge gas after the iridium precursor pulse;
pulsing a co-reactant into the reactor proximate to the semiconductor substrate;
purging the reactor with the purge gas after the co-reactant pulse;
transferring the semiconductor substrate to a plating bath; and
depositing a bulk copper layer on the semiconductor substrate using a plating process.

2. The method of claim 1, wherein the co-reactant comprises at least one of atomic hydrogen, molecular hydrogen, O₂, BH₃, B₂H₆, catechol-borane, NH₃, CH₄, SiH₄, GeH₄, metal hydrides, CO, or ethanol.

3. The method of claim 1, wherein the co-reactant comprises an H₂ plasma.

4. The method of claim 1, wherein the co-reactant comprises a metal precursor for aluminum, copper, ruthenium, or tantalum.

5. The method of claim 1, wherein the plating bath is intended for an electroplating process and the plating process comprises an electroplating process.

6. The method of claim 1, wherein the plating bath is intended for an electroless plating process and the plating process comprises an electroless plating process.

7. The method of claim 1, wherein the purge gas comprises Ar, Xe, N₂, He, or forming gas.

8. The method of claim 1, further comprising setting a reactor pressure to be between around 0.1 Torr and 3.0 Torr.

9. The method of claim 1, further comprising heating the semiconductor substrate to a temperature between around 100° C. and 400° C.

10. The method of claim 1, wherein the iridium precursor pulse has a time duration of between around 1 second and 10 seconds.

11. The method of claim 1, further comprising setting an iridium precursor flow rate to be up to 10 standard liters per minute (SLM).

12. The method of claim 1, further comprising heating the iridium precursor to a temperature between around 80° C. and 250° C.

13. The method of claim 1, wherein between 1 and 200 pulses of the iridium precursor are introduced into the reactor.

14. The method of claim 1, further comprising applying an RF energy source at a power that ranges from 5 W to 200 W and at a frequency of either 13.56 MHz, 27 MHz, or 60 MHz.

15. The method of claim 1, wherein a time duration of the purging of the reactor ranges from 0.1 seconds to 60 seconds.

16. The method of claim 2, wherein a time duration for the co-reactant pulse is between around 1 second and around 10 seconds.

17. The method of claim 2, wherein a flow rate for the co-reactant pulse ranges up to 10 SLM.

18. The method of claim 2, wherein a temperature for the co-reactant ranges between around 80° C. and 200° C.

19. The method of claim 3, wherein a time duration for the H₂ plasma pulse is between around 2 seconds and around 10 seconds.

20. The method of claim 3, wherein a flow rate for the H₂ plasma pulse is between around 200 SCCM to around 600 SCCM.

21. The method of claim 2, wherein a power for the H₂ plasma pulse ranges between around 5 W and around 200 W.

22. The method of claim 1, further comprising repeating the pulsing of the iridium precursor, the purging the reactor, the pulsing the co-reactant, and the purging the reactor until a resulting iridium layer reaches a desired thickness.

23. An apparatus comprising:
an iridium layer formed within a trench in a dielectric layer, wherein the iridium layer is formed directly on the dielectric layer; and
a copper interconnect formed on the iridium layer;
wherein the iridium layer is formed using an atomic layer deposition process in which an iridium precursor comprises at least one of Ir₄(CO)₁₂, Ir(CO)_{y}Br_{4-y}, Ir(CO)_{y}Cl_{4-y}, Ir(CO)_{y}I_{4-y}, HIr(CO)₄, (Ir(CO)₂Cl)₂, IrH₃(PPh₃)₂, IrH₂Cl(PPh₃)₃, (IrCl(PF₃)₂)₂, Ir(acac)₃, Ir(allyl)₂(acac), Ir(hfac)(C₂H₄)₂, Ir(Cp)₂, Ir(Cp)(CpMe₅), Ir(Benzene)(CpMe₅), IrCl(CO)(PPh₃)₂, IrH(CO)(PPh₃)₃, IrH₂Cl(CO)(PPh₃)₂, IrCl₂(Cp)(PPh₃), Ir(CO)(Cp)(PPh₃), MeCplr(COD), or MeCplr(norboradiene).

24. The apparatus of claim 23, wherein the copper interconnect is formed using an electroplating process.

25. The apparatus of claim 23, wherein the copper interconnect is formed using an electroless plating process.

26. The apparatus of claim 23, wherein the iridium layer is between 1 nm and 10 nm thick.
